(19) United States
(12) Patent Application Publication
(10) Pub. No.: US 2024/0272033 A1
(43) Pub. Date: Aug. 15, 2024

(54) Method for Detecting a Hydrogen Leak in a Fuel Cell System and Fuel Cell System for Implementing Such a Method

(71) Applicant: SYMBIO FRANCE, Venissieux (FR)

(72) Inventors: Gino Paganelli, Cottens (CH); Lionel Jeanrichard-Dit-Bressel, Formangueires (CH)

(21) Appl. No.: 18/568,075

(22) PCT Filed: Jun. 10, 2022
(86) PCT No.: PCT/EP2022/065911

§ 371 Date: Dec. 7, 2023

(30) Foreign Application Priority Data
Jun. 11, 2021 (FR) FR2106189

(51) Int. Cl. G01M 3/26; H01M 8/04082; H01M 8/04089; H01M 8/04223; H01M 8/0438; H01M 8/10

(52) U.S. Cl. CPC G01M 3/26; H01M 8/04097; H01M 8/04201; H01M 8/04231; H01M 8/0438; H01M 2008/1095

(57) ABSTRACT

This method for detecting a hydrogen leak applies to a fuel cell system (10) comprising a fuel cell (12); a hydrogen supply system (30) comprising a reservoir (32) and the supply circuit (34) connecting the reservoir to the anode compartment (16) of the fuel cell and comprising an ejector (36) of Venturi type; a recirculation circuit (60) for recirculating unconsumed hydrogen between the anode compartment of the cell and the Venturi-type ejector (36), the recirculation being driven by the Venturi-effect ejector. The method comprises steps involving calculating the total flow rate of hydrogen consumed; calculating the flow rate of hydrogen admitted to the ejector; determining the leak rate as the difference between the flowrate of hydrogen admitted and the total flow rate of hydrogen consumed; and detecting a potential leak of hydrogen by comparing the leak rate against at least a threshold value, such that the method detects all of the hydrogen leaks that occur in the system downstream of the ejector.

The present invention relates to a method for detecting a hydrogen leak in a fuel cell system and a fuel cell system for implementing such a method.

A fuel cell system typically comprises a fuel cell for the production of electrical energy by an electrochemical reaction, together with a hydrogen supply system and a purge system to enable the operation of the fuel cell.

A fuel cell generally comprises a series of individual elements, each of which consists essentially of an anode and a cathode separated by a polymer membrane that allows protons to pass from the anode to the cathode. The anode, supplied with hydrogen, is the site of an oxidation half-reaction H₂ (g)=>2H⁺(aq)+2 e⁻. At the same time, the cathode is supplied with oxidant, for example pure oxygen or oxygen contained in air, and undergoes a half-reduction reaction: 0₂ (g)+4H⁺(aq)+4 e⁻=>2 H₂O (l).

It is known from WO 2018/115630 A1 to add, to a fuel cell system, a system for recirculating hydrogen not consumed by the fuel cell. Such a recirculation system improves the performance of the fuel cell. It is also known from this document that a Venturi-type ejector is used to recirculate unconsumed hydrogen from the fuel cell anode outlet to the anode inlet.

However, the disadvantage of such a fuel cell system is that it is not possible to estimate hydrogen leakage from the fuel cell system. Detecting such leaks is important to ensure the safe operation of the fuel cell system and to maintain optimum performance, without avoidable losses of hydrogen.

It is known to measure the flow rate of hydrogen supplied to a fuel cell using a flow meter installed on the fuel cell's hydrogen supply line. However, the use of a flowmeter is restrictive, as a flowmeter is generally bulky and has a pressure drop that is detrimental to the efficiency of the fuel cell. What's more, an accurate flow meter is expensive.

KR 10-1393581 discloses a method for determining hydrogen leakage in a fuel cell system during operation. This method is based on the difference between the hydrogen consumption calculated according to the current produced by the fuel cell and the hydrogen consumption estimated based on the pressure drop across a hydrogen supply valve.

However, this method is not very accurate, particularly for low-intensity hydrogen leaks. In particular, estimating the quantity of hydrogen supplied to the fuel cell system as a function of the operating parameters of a supply valve requires both approximations and expensive specific equipment.

These drawbacks are what the invention is intended to more particularly address, by proposing an improved method for detecting hydrogen leaks in a fuel cell system.

To this end, the invention relates to a method of detecting hydrogen leakage in a fuel cell system, the fuel cell system comprising at least:
a stack of electrochemical cells forming a fuel cell comprising an anode compartment and a cathode compartment separated by a polymer proton exchange membrane;
a hydrogen supply system comprising a hydrogen reservoir and a supply circuit connecting the hydrogen reservoir to the inlet of the anode compartment of the fuel cell, the supply circuit comprising a Venturi-type ejector;
a recirculation circuit for recirculating hydrogen not consumed by the fuel cell between the outlet of the anode compartment of the fuel cell and the Venturi-type ejector of the supply circuit, the recirculation of the unconsumed hydrogen being driven by the Venturi-type ejector; and
a purge system comprising a valve for purging and draining the anode compartment.

According to the invention, the hydrogen leakage detection method comprises at least the following steps:
a) calculating the total flow of hydrogen consumed by the fuel cell system; b) calculating the hydrogen flow rate admitted by the hydrogen supply system into the inlet of the Venturi ejector;
c) determining the leak rate by calculating the difference between the admitted hydrogen flow rate and the total hydrogen flow rate consumed; and
d) detecting a possible hydrogen leak in the fuel cell system by comparing the leak rate against at least one threshold value,
such that the method detects all of the hydrogen leaks that occur in the fuel cell system downstream of the Venturi-type ejector.

Thanks to the invention, the method for detecting a hydrogen leak in a fuel cell system makes it possible to detect a hydrogen leak with a high degree of accuracy, regardless of the location of this leak in the fuel cell system, even in the case of a low-intensity leak.

According to advantageous, but not mandatory, aspects of the invention, this method for detecting hydrogen leakage in a fuel cell system incorporates one or more of the following features, taken alone or in any technically permissible combinations:
In step a), the total flow rate of hydrogen consumed Q_{H2.out} by the fuel cell system is calculated from the following sum: Q_{H2.out}=Q_{H2.out}_{ₛₜₒ}+Q_{H2.out}_{ₓₒ}+Q_{H2.out}_{_{purg}} where Q_{H2.out}_{ₛₜₒ} is the base flow rate of hydrogen consumed by the fuel cell by electrochemical reaction; Q_{H2.out}_{_{purg}} is the flow rate of hydrogen lost in the purges of the anode compartment of the fuel cell; and Q_{H2.out}_{ₓₒ} is the flow rate of hydrogen through the polymer proton exchange membrane from the anode compartment to the cathode compartment.
During step a), the flow rate of hydrogen lost Q_{H2.out}_{_{purg}} in the purges of the anode compartment of the fuel cell is calculated according to the following equation: Q_{H2.out}_{_{purg}}=

$${Q}_{H 2. ou {t}_{purg}} = \frac{M {W}_{h 2}}{R \times T} \times {V}_{a n o d e} \times {\dot{P}}_{a n o d e . i n}$$

where MWₕ₂ is the molar mass of dihydrogen, R is the ideal gas constant, T is the temperature in the anode compartment, V_{anode} is the volume of the anode compartment and \dot{P}_{anode.in} is the pressure gradient measured at the entrance to the anode compartment during a purge.
The pressure gradient \dot{P}_{anode.in} is obtained by a constant-intake purge method consisting of delaying the restoration of the pressure lost in the anode compartment of the fuel cell during a purge by delaying the opening of a hydrogen supply valve of the supply system.
During step a), the flow rate of hydrogen consumed by permeation Q_{H2.out}_{ₓₒ} through the polymer proton exchange membrane from the anode compartment to the cathode compartment is calculated according to the following equation:

$${Q}_{H 2. ou {t}_{x o}} = \frac{M {W}_{h 2} \times N}{2 \times F} \times {J}_{X o} \times {S}_{m e m b r a n e}$$

where MWₕ₂ is the molar mass of dihydrogen, N is the number of electrochemical cells in the fuel cell, F is Faraday's constant, J_{Xo} is the crossover current density, and S_{membrane} is the surface area of the membrane of an electrochemical cell.
During step b), the flow rate of hydrogen admitted Q_{H2.in} by the hydrogen supply system into the inlet pipe of the Venturi-type ejector is calculated according to whether the flow regime occurring within the Venturi-type ejector is a subsonic flow regime or a sonic flow regime.
When the flow regime is subsonic, the flow of hydrogen admitted Q_{H2.in}_{_{sub}} by the hydrogen supply system into the inlet pipe of the Venturi-type ejector is calculated according to the following equation:

$${Q}_{H 2. {in}_{s u b}} = δ \times {P}_{1} \times {A}_{C} \times \sqrt{\frac{2 \times M {W}_{h 2} \times γ}{R \times {T}_{1}}} \times \sqrt{\frac{{( \frac{{P}_{2}}{{P}_{1}} )}^{\frac{2}{γ}} - {( \frac{{P}_{2}}{{P}_{1}} )}^{\frac{1 + γ}{γ}}}{γ - 1}}$$

where P₁ is the pressure of the hydrogen admitted into the inlet pipe of the Venturi-type ejector, T₁ is the temperature of the hydrogen admitted into the intake of the Venturi-type ejector, P₂ is the pressure of the hydrogen leaving the Venturi-type ejector, δ is the efficiency of the sonic choke of the Venturi-type ejector, A_{C} is the smallest cross-sectional area of the sonic choke of the ejector, MWₕ₂ is the molar mass of dihydrogen, γ is the adiabatic coefficient of dihydrogen and R is the ideal gas constant. In addition, when the flow regime is sonic, the flow of hydrogen admitted Q_{H2.in}_{ₛₒₙ} by the hydrogen supply system into the inlet pipe of the Venturi-type ejector is calculated with the following equation:

$${Q}_{H 2 . i {n}_{s o n}} = δ \times {P}_{1} \times {A}_{C} \times \sqrt{\frac{M {W}_{h 2} \times γ}{R \times {T}_{1}}} \times {( \frac{2}{γ + 1} )}^{\frac{γ + 1}{2 \times ( γ - 1 )}}$$

where P₁ is the pressure of the hydrogen admitted into the inlet pipe of the Venturi-type ejector, T₁ is the temperature of the hydrogen admitted into the inlet pipe of the Venturi-type ejector, δ is the efficiency of the sonic choke of the Venturi-type ejector, A_{C} is the smallest cross-sectional area of the sonic choke of the ejector, MWₕ₂ is the molar mass of dihydrogen, γ is the adiabatic coefficient of dihydrogen and R is the ideal gas constant.
The leak rate determined in step c) is filtered before comparison with at least one threshold value.
The leak rate determined in step c) is filtered using two different filters and the results obtained by these two filters are compared with two different detection thresholds: a first leak detection threshold compared with the leak rate filtered with a first-order low-pass filter with a time constant equal to a first value; and a second leak detection threshold compared against the leak rate filtered with a first-order low-pass filter with a time constant equal to a second value. In addition, the first leak detection threshold has a higher value than the second leak detection threshold and the first time constant value is lower than the second time constant value.
The hydrogen leak detection method is performed cyclically, in real time, and preferably steps c) and d) of the hydrogen leak detection method are performed by a fuel cell system control computer at each sampling period of the computer.

According to another aspect, the invention also relates to a fuel cell system for implementing the hydrogen leak detection method described above, this fuel cell system comprising at least:
a stack of electrochemical cells forming a fuel cell comprising an anode compartment and a cathode compartment separated by a polymer proton exchange membrane;
a hydrogen supply system comprising a hydrogen reservoir and a supply circuit connecting the hydrogen reservoir to the inlet of the anode compartment of the fuel cell, the supply circuit comprising a Venturi-type ejector;
a recirculation circuit for recirculating hydrogen not consumed by the fuel cell between the outlet of the anode compartment of the fuel cell and the Venturi-type ejector of the supply circuit, the recirculation of the unconsumed hydrogen being driven by the Venturi-type ejector;
a purge system comprising a valve for purging and draining the anode compartment; and
a computer for implementing steps a) to d) of the hydrogen leak detection method.

This fuel cell system has the same advantages as those mentioned above for the leak detection method of the invention.

Advantageously, this fuel cell system further comprises a pressure sensor and a temperature sensor arranged upstream of the Venturi-type ejector and a pressure sensor arranged downstream of the Venturi-type ejector.

The invention will be better understood and advantages beyond these will emerge more clearly in light of the following description of a method for detecting hydrogen leakage in a fuel cell system and of a method for constructing a fuel cell system, both according to the invention, given solely by way of example and made with reference to the accompanying drawings, wherein:

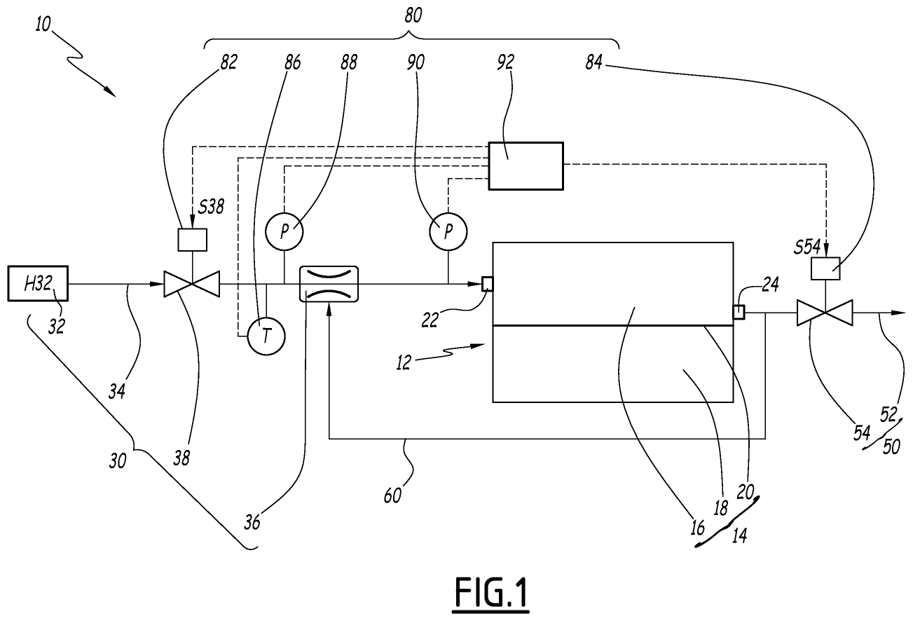

FIG. 1 is a fluid diagram of a fuel cell system according to the invention;

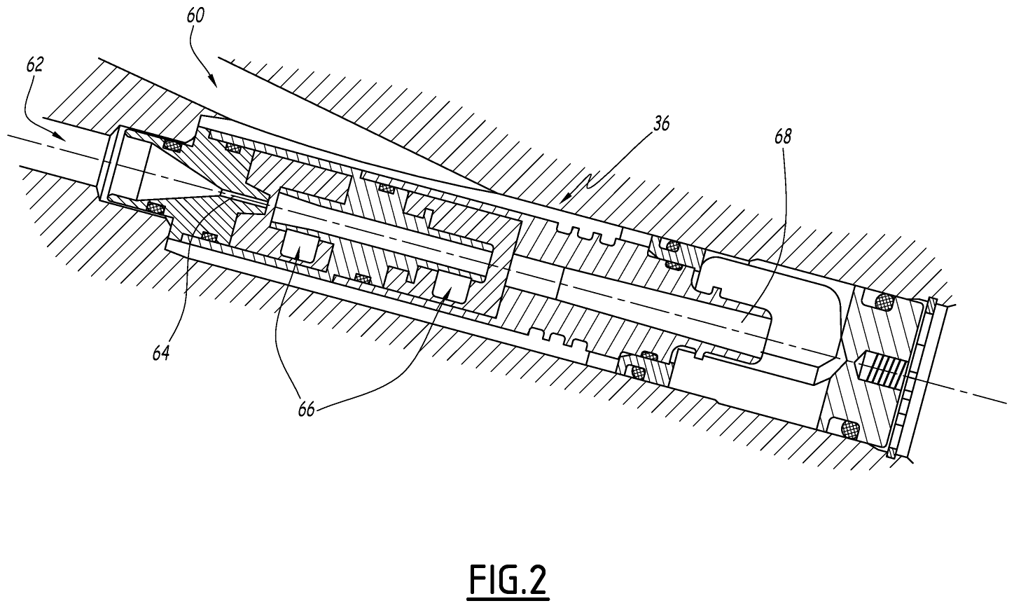

FIG. 2 is a detail view of part of the fuel cell system shown in FIG. 1;

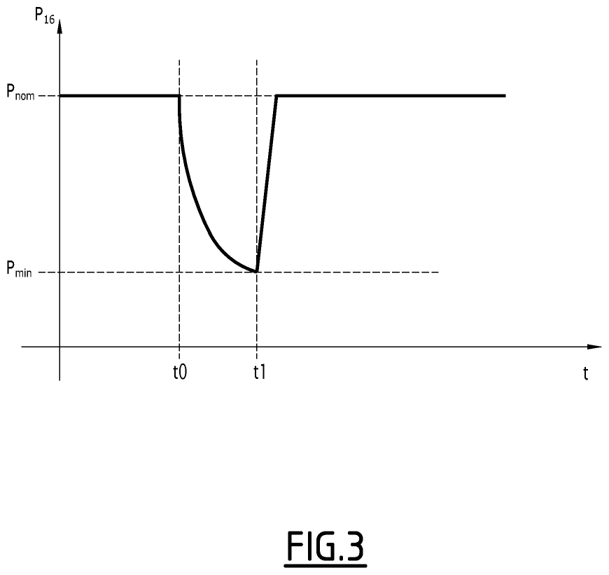

FIG. 3 is a graph showing the change overtime of the pressure measured by a sensor in the fuel cell system shown in FIG. 1;

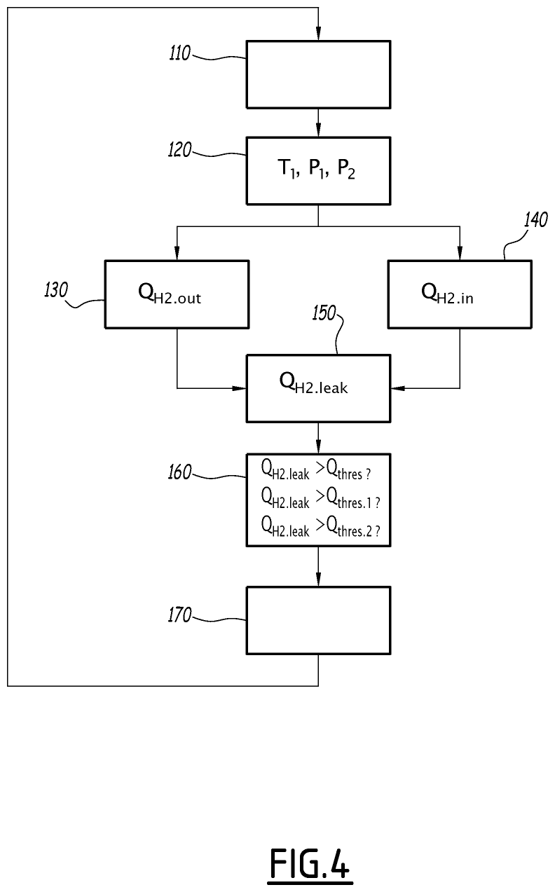

FIG. 4 is a diagram illustrating the steps of a method for detecting hydrogen leakage in a fuel cell system, the method being in accordance with the invention; and

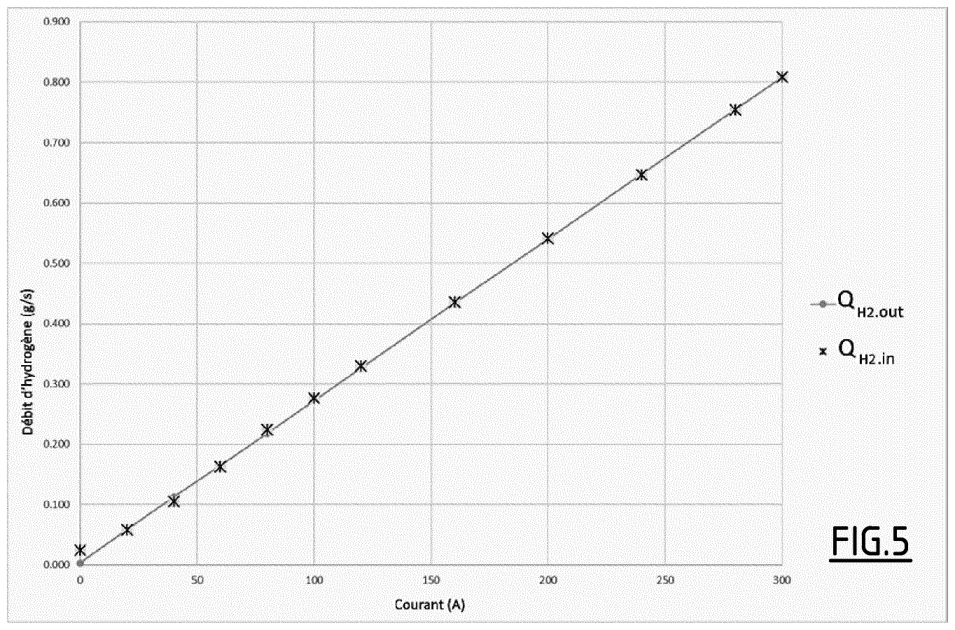

FIG. 5 is an example of the results obtained by the leak detection method illustrated in FIG. 4 applied to a fuel cell system without hydrogen leakage.

A fuel cell system 10 is shown in FIGS. 1 to 2. This fuel cell system is designed, for example, to be integrated into a vehicle with an electric motor in order to produce electrical energy to operate the motor.

This fuel cell system 10 comprises a fuel cell 12.

The fuel cell 12 comprises a stack of electrochemical cells 14, only one of which is shown in FIG. 1 for simplicity's sake.

In practice, the fuel cell 12 comprises a whole number N of electrochemical cells 14, N preferably being between 1 and several hundred, and even more preferably between 64 and 416.

Each electrochemical cell 14 comprises an anode compartment 16, which forms the anode of the electrochemical cell, and a cathode compartment 18, which forms the cathode of the electrochemical cell. The anode compartment 16 and the cathode compartment 18 are separated by a polymer proton exchange membrane 20.

During the operation of the fuel cell 12, the anode compartment 16 is supplied with fuel gas, generally pure dihydrogen, more commonly called hydrogen for simplicity's sake, and the cathode compartment 18 is supplied with oxidising gas, generally dioxygen, more commonly called oxygen for simplicity's sake, either pure or included in a mixture of gases, for example air.

In the remainder of the description, the terms “hydrogen” and “dihydrogen” are used interchangeably to refer to dihydrogen.

Thus, the fuel cell 12 comprises as many anode compartments 16, cathode compartments 18 and membranes 20 as electrochemical cells 14, i.e. N. For simplicity's sake, all the anode compartments are likened to a single anode compartment 16, which forms the anode of the fuel cell 12, all the cathode compartments are likened to a single cathode compartment 18, which forms the cathode of the fuel cell 12 and all the membranes 20 are likened to a single membrane 20, which separates the anode and cathode of the fuel cell 12.

An input 22 and an output 24 are defined in the anode compartment 16.

To supply hydrogen to the anode compartment 16, the fuel cell system 10 comprises a hydrogen supply system 30.

The hydrogen supply system 30 comprises a hydrogen reservoir 32 and a supply circuit 34 connecting the hydrogen reservoir 32 to the inlet 22 of the anode compartment 16. In this way, the inlet 22 is configured to let hydrogen into the anode compartment.

A Venturi-type ejector 36 and a supply valve 38, located between the ejector 36 and the hydrogen reservoir 32, are installed on the supply circuit 34.

Preferably, one or more shut-off valves, not shown, are installed between the hydrogen reservoir 32 and the supply valve 38.

The supply valve 38 is used to control the flow of hydrogen supplied by the hydrogen reservoir 32 to the fuel cell 12. Thus, the supply valve 38 is a proportional valve, i.e. it delivers a flow of hydrogen proportional to its opening.

To purge and drain the anode compartment 16, the fuel cell system 10 comprises a purge system 50. The purge system 50 comprises a purge circuit 52 which connects the outlet 24 of the anode compartment 16 with the outside of the fuel cell system 10, for example the atmosphere, and a purge and drain valve 54 installed on the purge circuit 52 and enabling, or preventing, purging depending on whether it is open or closed. In this way, the purge and drain valve 54 allows a so-called “discontinuous” purge of the anode compartment 16. In this way, the outlet 24 is configured to allow gases and/or liquids to escape from the anode compartment 16.

In practice, the purge and drain valve 54 is, for example, an “on/off” solenoid valve.

The purge system 50 is used to purge the anode compartment 16 of liquid water and non-combustible gases, such as nitrogen or water vapour, which may accumulate there.

The fuel cell system 10 further comprises a recirculation system 60.

In practice, the recirculation system 60 is a circuit connecting the outlet 24 of the anode compartment 16 to the Venturi-type ejector 36 of the supply circuit 34, which enables hydrogen to be recirculated.

In a manner known per se, the recirculation system 60 comprises hydrogen separation means, not shown, which enable the hydrogen not consumed by the fuel cell 12 to be separated from the liquid water present at the outlet 24 of the anode compartment 16, thus enabling no liquid water to be recirculated.

This hydrogen recirculation is advantageous because it improves fuel cell performance without increasing hydrogen consumption. In particular, this recirculation ensures a sufficient flow of hydrogen within the anode compartment 16 of the fuel cell 12 to prevent any accumulation of liquid water in the anode compartment and thus avoid local shortages of hydrogen, thereby ensuring optimum efficiency and durability of the fuel cell.

In addition, the hydrogen recirculation is driven by the Venturi-type ejector 36, by the Venturi effect.

As can be seen more clearly in FIG. 2, the ejector 36 comprises a hydrogen inlet pipe 62, which in practice is connected to the part of the supply circuit 34 located upstream of the ejector.

The ejector 36 also comprises a sonic choke 64, into which all the hydrogen admitted through the hydrogen inlet pipe 62 is channelled. The effect of this sonic choke is to increase the speed of the hydrogen and decrease the pressure of the hydrogen, until a vacuum is created downstream of the sonic choke 64.

The ejector 36 also comprises vents 66, arranged downstream of the sonic choke 64, which are connected to the downstream end of the recirculation system 60. The recirculation system 60 therefore opens into the Venturi-type ejector 36 at the vents 66.

The negative pressure created downstream of the sonic choke 64 by the Venturi effect causes suction through the vents 66, which enables the hydrogen contained in the recirculation system to be sucked out and thus circulate the hydrogen in this system.

The ejector 36 also comprises an outlet pipe 68, connected to the part of the supply circuit 34 located downstream of the ejector. The outlet nozzle 68 of the ejector is therefore connected to the inlet 22 of the anode compartment 16 of the fuel cell 12, via a section of the supply circuit.

Thus, the hydrogen flow rate at the inlet of the ejector 36 corresponds to the hydrogen flow rate supplied by the hydrogen reservoir 32 and the hydrogen flow rate at the outlet of the ejector corresponds to the sum of the hydrogen flow rate supplied by the hydrogen reservoir and the hydrogen flow rate recirculated within the recirculation system 60.

The fuel cell system 10 further comprises a control system 80.

The control system 80 comprises, among other things, two actuators 82, 84, a temperature sensor 86, two pressure sensors 88 and 90 and a computer 92.

The actuators 82 and 84 are solenoids, for example, and are used to operate the supply valve 38 and the purge valve 54 respectively.

The actuator 82 allows the supply valve 38 to be opened progressively and thus regulates the flow of hydrogen supplied to the ejector 36 by the supply circuit 34 in proportion to the opening of the supply valve 38.

The actuator 84 is used to open and close the purge and drain valve 54 and thus to initiate and interrupt a purge of the anode compartment 16 of the fuel cell 12.

The temperature sensor 86 and the first pressure sensor 88 are installed in the supply circuit 34 upstream of the Venturi-type ejector 36. In practice, these two sensors are positioned as close as possible to the hydrogen inlet pipe 62 of the ejector 36, therefore downstream of the supply valve 38, so as to measure the temperature and pressure respectively of the gas entering the ejector.

“T₁” is the temperature of the hydrogen admitted to the inlet of the ejector 36, measured by the temperature sensor 86.

“P₁” is the pressure of the hydrogen admitted to the inlet of the ejector 36, measured by the pressure sensor 88.

The second pressure sensor 90 is installed on the supply circuit 34 downstream of the ejector 36.

“P₂” is the pressure of the hydrogen exiting the ejector 36, measured by the pressure sensor 90.

In practice, the computer 92 may be a computer, an integrated circuit board equipped with a microprocessor, a programmable logic controller, or software running on a server.

Preferably, the computer 92 is a computer for controlling the fuel cell 10.

The computer 92 controls the actuators 82 and 84 and retrieves data from the temperature sensor 86 and the pressure sensors 88 and 90.

Advantageously, the computer 92 runs software for controlling the fuel cell system 10.

In particular, the computer 92 can adapt the flow rate of hydrogen supplied to the fuel cell 12 by adjusting the opening of the valve 38 as a function of fuel cell operating parameters, such as the hydrogen pressure P₂ measured at the inlet to the anode compartment 16.

The computer 92 sends a signal S₃₈ controlling the opening of the valve 38 to the actuator 82, the control being proportional to the flow of hydrogen to be supplied to the fuel cell 12. This valve opening control signal S₃₈ is updated in real time during the operation of the fuel cell system 10.

The computer 92 can also control the purging of the anode compartment 16 by controlling the opening of the purge and drain valve 54, by means of a signal S₅₄ sent to this valve, for example at a predefined frequency or as a function of the operating parameters of the fuel cell 12.

Advantageously, the hydrogen used in the fuel cell system 10 is very dry and very pure, i.e. the gas stored in the hydrogen reservoir 32 is at least 99.97% dihydrogen.

The presence of other gases in the hydrogen admitted to the inlet pipe 62 of the ejector 36, such as water vapour, is therefore ignored.

Consequently, the properties of pure dihydrogen are used in the calculations presented in the rest of the description.

In addition, in the calculations presented in the rest of the description, the temperature T₁ is expressed in kelvin (K) and the pressures P₁ and P₂ are expressed in pascals (P) or in bar.

An example of a method for purging the anode compartment 16 using the purge system 50, as implemented in the fuel cell system 10, is now described in more detail with reference to FIG. 3.

This example of a purging method is not limiting, and other methods of purging the anode compartment 16 can be implemented without departing from the scope of the invention.

FIG. 3 shows the change in the pressure P₁₆ in the anode compartment 16 during a discontinuous purge of the anode compartment 16 outward from the fuel cell system 10.

The pressure P₁₆ in the anode compartment 16 corresponds to the pressure P₂ measured by the pressure sensor 90, since the supply circuit 34 downstream of the ejector 36 and the anode compartment 16 are directly connected via the inlet 22 of the anode compartment.

Before purging the anode compartment 16, the pressure P₁₆ in the anode compartment 16 is equal to a nominal pressure, denoted “Pₙₒₘ”.

In practice, to purge the anode compartment 16, the purge valve 54 is opened on command from the computer 92, for a predefined time interval, between instants t₀ and t₁.

When the purge valve 54 is opened, i.e. at time to, the signal S₃₈ for controlling the opening of the supply valve 38 sent by the computer 92 is frozen, so that between t₀ and t₁, the opening of the supply valve 38 is maintained at a constant level. Thus, between t₀ and t₁, the flow of hydrogen supplied by the supply circuit 34 to the ejector 36 is constant. This is known as “constant-intake purging”.

As can be seen in FIG. 3, opening the purge valve 54 leads to a reduction in pressure in the anode compartment 16. Since the opening of the supply valve 38 is fixed during purging, the gas escaping outward via the purge valve 54 is not replaced.

The pressure in the anode compartment 16 then drops to a minimum, denoted “Pₘᵢₙ”.

During the time the bleed valve 54 is open, between t₀ and t₁, a pressure gradient is observed.

From this pressure gradient, it is possible to calculate a purged hydrogen flow rate Q_{H2.out}_{_{purg}}, in grams per second (g/s) using the following equation:

$${Q}_{H 2. {out}_{purg}} = \frac{M {W}_{h 2}}{R \times T} \times {V}_{anode} \times {\dot{P}}_{a node . i n} \qquad [ Equation 1 ]$$

where:
MWₕ₂ is the molar mass of dihydrogen, in practice equal to 2.0159 grams per mole (g/mol),
R is the ideal gas constant, in Joules per mole kelvin (J×mol⁻¹×K⁻¹), equal to approximately 8.314 J×mol⁻¹×K⁻¹,
T is the temperature within the anode compartment 16, expressed in Kelvin, measured by a sensor not shown in the figures,
V_{anode} is the volume of the anode compartment 16, in litres (I), and
\dot{P}_{anode.in} is the pressure gradient P₂ measured at the inlet to the anode compartment 16 by the pressure sensor 90 during a purge, in bars per second (bar/s).

The presence of non-combustible gases, such as nitrogen or water vapour, in the anode compartment 16 is ignored for this calculation because, in practice, these gases have a negligible influence.

Advantageously, the hydrogen purge flow rate is calculated by the computer 92 in real time.

Thanks to this method of purging the anode compartment, it is possible to know in real time the flow of hydrogen Q_{H2.out}_{_{purg}} lost in the purges of the anode compartment 16.

At the end of the purge, i.e. at the time t₁ corresponding to the closure of the purge valve 54, the computer 92 sends a modified opening control signal S₃₄ to the actuator 82 of the supply valve 38, so as to restore the pressure lost in the anode compartment 16 during the purge.

As can be seen in FIG. 3, the opening control is adapted so as to increase the flow of hydrogen admitted from the minimum pressure Pₘᵢₙ until it reaches a pressure P₁₆ equal to the nominal pressure Pₙₒₘ in the anode compartment 16.

According to this purging method, the modification of the opening command of the supply valve 38 allowing the increase of the admitted hydrogen flow rate, and thus the restoration of the nominal pressure Pₙₒₘ, is delayed in time with respect to the opening of the purge and drain valve 54, which makes it possible to generate a pressure gradient and thus to calculate the purged hydrogen flow rate, by means of equation 1. This method is known as “deferred purging”.

In practice, the opening time of the purge and drain valve 54, which corresponds to the purge time between time to and time t₁, is between 0.1 second and 1 second. For example, the purge duration is equal to 0.2 seconds.

In this way, the time lag between the opening of the purge and drain valve 54 and the admission of hydrogen to compensate for the loss of hydrogen due to purging is negligible. The decrease in pressure between the nominal pressure Pₙₒₘ and the minimum pressure Pₘᵢₙ therefore has no impact on the operation of the fuel cell 12.

An example of a method for detecting hydrogen leakage in the fuel cell system 10 in accordance with the invention is now described in more detail with reference to FIG. 4.

Preferably, this hydrogen leak detection method is implemented automatically by the computer 92.

The hydrogen leak detection method is carried out in real time. In addition, this method is carried out cyclically. The steps carried out in each cycle of the hydrogen leak detection method in accordance with the invention are now described.

This method includes an initial start-up step 110.

This method includes a second measurement step 120, carried out after the start-up step 110. During this stage, the temperature T₁ is measured by the temperature sensor 86, the pressure P₁ is measured by the first pressure sensor 88 and the pressure P₂ is measured by the second pressure sensor 90, then the data from the sensors 86, 88 and 90 is transmitted to the computer 92.

The method comprises a third step 130 of calculating the total flow rate of hydrogen consumed by the fuel cell system 10, subsequent to the measurement step 120.

This total flow of hydrogen consumed is denoted Q_{H2.out}.

The total flow of hydrogen Q_{H2.out} consumed by the fuel cell 10 system is calculated using the following equation:

$${Q}_{H 2. out} = {Q}_{H 2. {out}_{sto}} + {Q}_{H 2. {out}_{xo}} + {Q}_{H 2. {out}_{purg}} \qquad [ Equation 2 ]$$

where:
Q_{H2.out}_{ₛₜₒ} is a base rate of hydrogen consumed by the electrochemical reaction occurring in the electrochemical cells 14 of the fuel cell 12;
Q_{H2.out}_{ₓₒ} is a rate of hydrogen consumed by permeation of the polymer proton exchange membrane 20; and
Q_{H2.out}_{_{purg}} is the purged hydrogen flow rate calculated using equation 1 introduced above, corresponding to the loss of hydrogen in the purges.

The purged hydrogen flow rate Q_{H2.out}_{_{purg}} is zero when no purging of the fuel cell system 10 is in progress.

The base flow rate Q_{H2.out}_{ₛₜₒ} of hydrogen consumed by the fuel cell 12 is linked by a stoichiometric relationship to the electrical current produced by the fuel cell. This basic flow rate is also called “stoichiometric consumption” and is calculated using the following equation:

$${Q}_{H 2. {out}_{sto}} = \frac{{MW}_{h 2} \times N}{2 \times F} \times I \qquad [ Equation 3 ]$$

where:
MWₕ₂ is the molar mass of dihydrogen, in practice equal to 2.0159 grams per mole (g/mol),
N is the number of electrochemical cells 14 in the fuel cell 12;
F is Faraday's constant, in practice equal to 96485 Coulombs per mole (Coulombs/mol), also expressed in ampere-seconds per mole (A×s×mol⁻¹); and
I is the current generated by the fuel cell 12, in amperes (A).

Equation 3 shows that the stoichiometric consumption Q_{H2.out}_{ₛₜₒ} of the fuel cell 12 is directly proportional to the current generated by the fuel cell.

The flow rate Q_{H2.out}_{ₓₒ} of hydrogen consumed by permeation through the polymer proton exchange membrane 20 corresponds to a flow rate of hydrogen transferred from the anode to the cathode during normal operation of the fuel cell 12, i.e. a flow rate of hydrogen passing through the membrane 20.

This transfer of hydrogen by permeation is also called the “crossover” mechanism and occurs under the effect of the osmotic pressure occurring in the electrochemical cells 14 due to the large difference in hydrogen concentration on either side of the membrane 20. The rate of hydrogen transfer is expressed as an equivalent crossover current.

The flow rate Q_{H2.out}_{ₓₒ} of hydrogen consumed by permeation is calculated using the following equation:

$${Q}_{H 2. {out}_{xo}} = \frac{{MW}_{h 2} \times N}{2 \times F} \times {J}_{Xo} \times {S}_{membrane} \qquad [ Equation 4 ]$$

where, in addition to the variables mentioned with reference to equation 3:
J_{Xo} is the crossover current density, in amperes per square centimetre (A/cm²); and
S_{membrane} is the surface area of the membrane 20 of an electrochemical cell 14, in square centimetres (cm²), which is known and constant.

Equation 4 shows that the flow rate Q_{H2.out}_{ₓₒ} of hydrogen consumed by permeation is directly proportional to the crossover current, which depends on the properties and characteristics of the polymer proton exchange membrane 20 used.

Thanks to experimental measurements and theoretical calculations, the evolution of this crossover current density over the lifetime of the fuel cell 12 is known. The increase in crossover current over the life of the battery is relatively small and can reasonably be ignored. The crossover current is very small compared to the main current generated by the fuel cell. Typically, the crossover current has a value of around 2 mA/cm2, while the main current generated by the fuel cell has a value of around 1 A/cm2. This results in a crossover flow rate, i.e. a flow rate of hydrogen consumed by permeation, approximately 500 times lower than the base flow rate, i.e. the flow rate of hydrogen consumed by the fuel cell 12.

In the third step 130, the total flow of hydrogen consumed by the fuel cell system 10 is therefore calculated by the computer 92 by applying equation 2 detailed above.

The method of detecting a hydrogen leak comprises a fourth step 140 of calculating the flow rate of hydrogen admitted by the hydrogen supply system to the inlet of the Venturi-type ejector, denoted “Q_{H2.in}”. This fourth step 140 is carried out by the computer 92 after the measurement step 120 and simultaneously with step 130.

More precisely, the flow of hydrogen admitted Q_{h2.in} corresponds to the flow of hydrogen through the hydrogen inlet pipe 62 and the sonic choke 64 of the Venturi-type ejector 36.

Calculation of the flow of hydrogen admitted Q_{H2.in} depends on the flow regime within the Venturi-type ejector 36: the flow of hydrogen in the ejector can take two types of flow regime, depending on whether the ratio of pressure P₂ to pressure P₁ is less than or greater than a critical pressure ratio denoted V_{cr}.

The critical pressure ratio V_{cr} is calculated according to the following equation:

$${V}_{cr} = {( \frac{2}{( γ + 1 )} )}^{\frac{γ}{γ - 1}} \qquad [ Equation 5 ]$$

where γ is the adiabatic coefficient of dihydrogen at temperature T₁ measured by the temperature sensor 86, also known as the Laplace coefficient.

So when

$$\frac{{P}_{2}}{{P}_{1}} > {V}_{cr} ,$$

the admitted hydrogen flow regime is subsonic, i.e. the Mach number of the inlet hydrogen flow is less than 1. In this case, Q_{H2.in}_{_{sub}} is the admitted hydrogen flow rate, calculated using the following equation:

$${Q}_{H 2. {in}_{sub}} = δ \times {P}_{1} \times {A}_{C} \times \sqrt{\frac{2 \times {MW}_{h 2} \times γ}{R \times {T}_{1}}} \times \sqrt{\frac{{( \frac{{P}_{2}}{{P}_{1}} )}^{\frac{2}{γ}} - {( \frac{{P}_{2}}{{P}_{1}} )}^{\frac{1 + γ}{γ}}}{γ - 1}} \qquad [ Equation 6 ]$$

where:
δ is the efficiency of sonic choke 64 to take friction losses into account. Preferably, δ is equal to 0.97. In practice S is adapted to each fuel cell system 10 through empirical calibration under controlled conditions;
A_{C} is the smallest cross-sectional area of the sonic choke 64, expressed in square metres (m²);
MWₕ₂ is the molar mass of dihydrogen;
γ is the adiabatic coefficient of dihydrogen at temperature T₁; and
R is the ideal gas constant, in Joules per mole kelvin (J×mol⁻¹×K⁻¹), equal to approximately 8.314 J×mol⁻¹×K⁻¹,

When

$$\frac{{P}_{2}}{{P}_{1}} > {V}_{cr} ,$$

the admitted hydrogen flow regime is sonic, i.e. the Mach number of the inlet hydrogen flow is equal to 1. In this case of a sonic flow regime, Q_{H2.in}_{ₛₒₙ} is the admitted hydrogen flow rate, calculated using the following equation:

$${Q}_{H 2. {in}_{son}} = δ \times {P}_{1} \times {A}_{C} \times \sqrt{\frac{2 \times {MW}_{h 2} \times γ}{R \times {T}_{1}}} \times {( \frac{2}{γ + 1} )}^{\frac{γ + 1}{2 \times ( γ - 1 )}} \qquad [ Equation 7 ]$$

with the variables mentioned in equation 6.

Thanks to equations 6 and 7 presented above, it is possible to calculate in step 140 the admitted hydrogen flow rate Q_{H2.in} as a function of temperature T₁ and pressures P₁ and P₂, whatever the hydrogen flow regime.

The hydrogen leak detection method comprises a fifth step 150 of calculating the hydrogen leak rate in the fuel cell system 10, performed by the computer 92 subsequently to steps 130 and 140. This hydrogen leak rate is denoted Q_{H2.leak} and is calculated using the following equation:

$${Q}_{H 2. leak} = {Q}_{H 2. in} - {Q}_{H 2. out} \qquad [ Equation 8 ]$$

where:
Q_{H2.in} is equal to Q_{H2.in}_{_{sub}}, calculated using equation 6 above, or to Q_{H2.in}_{ₛₒₙ}, calculated using equation 7 above, depending on whether the flow regime of the hydrogen admitted to the Venturi-type ejector 36 is subsonic or sonic; and
Q_{H2.out} is calculated using equation 2 above.

During normal operation of the fuel cell 12, the quantity of hydrogen consumed Q_{H2.out} is equal to the quantity of hydrogen admitted Q_{H2.in}. So any difference between these two values is due to a hydrogen leak.

It should be noted that this equality is not checked during the transient phases of operation of the fuel cell system 10, for example during start-up of the system, when the anode compartment 16 and the circuits are filling with hydrogen. The hydrogen leak detection method therefore does not apply to these transient phases.

The resulting hydrogen leak rate Q_{H2.leak} is expressed in grams per second (g/s).

It is therefore possible to calculate the rate of hydrogen leakage in the fuel cell system 10, downstream of the Venturi-type ejector 36, with only the temperature T₁ and pressure P₁ upstream of the ejector, the pressure P₂ downstream of the ejector and the electric current generated by the fuel cell 12 being measured.

The method includes a sixth step 160 of detecting hydrogen leakage in the fuel cell system 10. During this step, the hydrogen leak rate Q_{H2.leak} is compared with one or more threshold values to detect a possible hydrogen leak.

To carry out this comparison, a first approach is to directly compare the hydrogen leak rate Q_{H2.leak} calculated during step 150 with a predefined leak detection threshold value, Qₜₕᵣₑₛ. If the calculated leak rate exceeds this threshold value Qₜₕᵣₑₛ, then the calculator 92 concludes that there is a leak. However, this approach has the disadvantage of being sensitive to measurement noise.

A second approach is therefore preferred for this comparison. This consists of filtering the calculated hydrogen leak rate Q_{H2.leak} before comparing it with one or more leak detection threshold values.

Preferably, the filtering applied to the hydrogen leak rate Q_{H2.leak} is a first-order low-pass filter.

For example, the hydrogen leak rate Q_{H2.leak} is filtered using a first-order low-pass filter with a time constant of ten seconds and the leak detection threshold Qₜₕᵣₑₛ is set at 30 milligrams per second (mg/s).

The choice of a first-order low-pass filter with a time constant of ten seconds is advantageous because it eliminates measurement noise and the variability of measurements over time, while providing a reactive detection method, i.e. one that can detect a hydrogen leak very quickly after it occurs, and with a high degree of accuracy.

It has been observed that when the flow rate of hydrogen admitted to the fuel cell system 10 is very low or zero, i.e. when the electric current produced by the fuel cell 12 is very low or zero, a residual measurement error is unavoidable. To avoid this residual measurement error leading to the detection of a hydrogen leak during step 160, which would then be a “false positive”, it is advantageous to ignore small leaks, with a low flow rate of hydrogen admitted.

To do this, the hydrogen leak rate Q_{h2,leak} is filtered using two different filters, then the results obtained by these two filters are compared with two different detection thresholds, denoted Q_{thres.1} and Q_{thres.2}, in a variant of step 160.

For example, the two leak detection thresholds are defined as follows:
the hydrogen leak rate Q_{H2.leak} is filtered using a first-order low-pass filter with a time constant of one second and the leak detection threshold Q_{thres.1} is set at 60 milligrams per second (mg/s); and
the hydrogen leak rate Q_{H2.leak} is filtered using a first-order low-pass filter with a time constant of 10 seconds and the leak detection threshold Q_{thres.2} is set at 30 milligrams per second (mg/s); and

In this example, to determine whether a hydrogen leak is taking place in the fuel cell system 10, the first detection threshold Q_{thres.1} is always used (A) and the second, more selective, detection threshold Q_{thres.2} is used only when the current produced by the fuel cell 12 is greater than or equal to 10 A.

In this way, the highest detection threshold is only considered when the admitted hydrogen flow rate is low, which avoids detecting a “false positive” caused by the inaccuracy of measurements at low flow rates.

Other values can be chosen for the time constants of the two first-order low-pass filters, and for the associated detection thresholds Q_{thres.1} and Q_{thres.2}.

Generally speaking, the value of the time constant and the detection threshold of a first filter are respectively less than and greater than the value of the time constant and the detection threshold of a second filter.

It should also be noted that filtering the hydrogen leakage flow Q_{H2.leak} eliminates the influence of the phase shift occurring during a purge between the opening of the purge and drain valve 54 and the admission of hydrogen compensating for the loss of hydrogen due to the purge, as the duration of a purge is much less than the time constant of the filters used.

The hydrogen leak detection method comprises a seventh, end-of-cycle step 170, performed after the hydrogen leak detection step 160 has been carried out.

During the end-of-cycle step 170, if the computer 92 detects that the fuel cell system 10 is still operating, then the hydrogen leak detection method starts a new cycle by performing steps 110 to 170 again, starting with the start-up step 110.

Thus, throughout the operation of the fuel cell system 10, the hydrogen leak detection method is executed in real time.

In practice, this means that the data from the temperature 86 and pressure 88 and 90 sensors are transmitted in real time to the computer 92, as well as the measurement of the current produced by the fuel cell 10, and that a complete cycle of the hydrogen leak detection method is carried out at each sampling period of the computer 92.

The sampling period of the computer 92 is, for example, between 1 millisecond and 10 milliseconds (ms).

More specifically, at each sampling period of the computer 92, the computer performs the calculations of steps 130, 140 and 150 and performs the hydrogen leak detection step 160.

We now describe in more detail, with reference to FIG. 5, the experimental results obtained by the hydrogen leak detection method applied to a fuel cell system 10 produced in accordance with the invention and having no detectable hydrogen leak.

FIG. 5 compares:
calculation of the flow of hydrogen consumed Q_{H2.out} by the fuel cell 12, using equation 2 above, with
calculation of the hydrogen flow rate Q_{H2.in} admitted to the inlet of the Venturi-type ejector 36, using equations 6 and 7 above.

This comparison is carried out at numerous operating points of the fuel cell 12, i.e. for different values of electrical current produced by the fuel cell. These different values of electric current produced are shown on the x-axis and the calculated hydrogen flow rates Q_{H2.out} and Q_{H2.in} are shown on the y-axis.

To obtain these experimental results, the following relationships were applied to calculate the admitted hydrogen flow rate Q_{H2.in}:

$${Q}_{H 2. {in}_{sub}} = 3 , 624 \times {P}_{1} \sqrt{\frac{{( \frac{{P}_{2}}{{P}_{1}} )}^{1 , 423} - {( \frac{{P}_{2}}{{P}_{1}} )}^{1 , 712}}{0.405 \times {T}_{1}}} \qquad [ Equation 9 ]$$

$${Q}_{H 2. {in}_{son}} = 1 , 482 \times {P}_{1} \sqrt{\frac{1}{{T}_{1}}} \qquad [ Equation 10 ]$$

To obtain these relationships, the following parameters were used:
A_{c}: smallest cross-sectional area of the sonic choke 64 equal to 1.43×10−6 m²;
γ: adiabatic coefficient of dihydrogen equal to 1.405;
δ: equal to 0.97;
MWₕ₂: molar mass of dihydrogen, equal to 2.0159 g/mol; and
R universal gas constant, equal to approximately 8.314 J×mol⁻¹×K⁻¹.

FIG. 5 shows that over the entire operating range of the fuel cell 12, the differences between the calculation of the flow of hydrogen consumed Q_{H2.out} and the calculation of the flow of hydrogen admitted Q_{H2.in} are less than 10 milligrams per second (mg/s), except when the current produced by the fuel cell 12 is low, in practice less than 10 A, where measurement inaccuracies lead to an error in the calculation of the flow of hydrogen admitted Q_{H2.in} of approximately 25 milligrams per second (mg/s).

Thanks to this comparison between the calculation of the flow of hydrogen consumed and the calculation of the flow of hydrogen admitted in the absence of a leak, the filtering thresholds used in step 160 in the case where two leak detection thresholds are used can be defined.

In addition, the small deviations shown in FIG. 5 demonstrate the accuracy of the calculations used by the hydrogen leak detection method, in particular the accuracy of equations 1 to 8.

Thus, the comparison shown in FIG. 5 corresponds to experimental confirmation on a fuel cell system 10 of the accuracy of the hydrogen leak detection method.

By “accurate”, it is meant here that the fuel cell system 10 and the hydrogen leak detection method have the following advantages:
good resolution, i.e. the smallest variation in the calculation of the flow of hydrogen consumed Q_{H2.out} and the calculation of the flow of hydrogen admitted Q_{H2.in} is small, in practice on the order of 1 milligram per second (mg/s); and
good accuracy, i.e. the error between the flow rates of hydrogen consumed Q_{H2.out} and hydrogen admitted Q_{H2.in} calculated by the leak detection method and the actual flow rates of hydrogen consumed and hydrogen admitted is small, in practice less than 2% FS (abbreviation of “full scale”, i.e. the percentages are expressed as a percentage of the full scale) for an electric current produced by the hydrogen cell 12 greater than or equal to 10 A and less than 4% FS for an electric current produced of less than 10 A.

The invention therefore makes it possible to propose a method for accurately detecting, in real time, hydrogen leaks occurring in a fuel cell system.

In addition, thanks to the invention, the physical principle of gas flow within the Venturi-type ejector 36 is used to enable the hydrogen leak detection method to be implemented.

Furthermore, the invention's hydrogen leak detection method only requires the use of measurement tools that are simple to integrate into the fuel cell 10 system and inexpensive.

The invention's leak detection method requires only the use of a temperature sensor 86 and two pressure sensors 88 and 90. These sensors can also be used to perform other functions in the fuel cell system 10.

For example, the second pressure sensor 90 is required to know the hydrogen pressure in the anode compartment 16 of the fuel cell 12, and thus regulate the admission of hydrogen into this anode compartment via the supply valve 38.

Thus, it is simple and inexpensive to adapt a fuel cell system so that the leak detection method of the invention can be implemented.

The leak detection method of the invention also has the advantage of being carried out during operation of the fuel cell system 10, which is safer because it enables a leak triggered during operation of the system to be detected.

The leak detection method of the invention also has the advantage of not affecting the operation or efficiency of the fuel cell system 10, which means that the operating costs of the system are not increased.

The leak detection method of the invention also has the advantage of making it possible to detect all the leaks occurring in the fuel cell system 10 downstream of the Venturi-type ejector 36, regardless of the location in the system of these leaks, since the method is based on the comparison between the flow rate of hydrogen consumed and the flow rate of hydrogen admitted. In other words, steps 130, 140, 150 and 160 are such that the method detects all hydrogen leaks occurring in the fuel cell system downstream of the Venturi-type ejector, i.e. the hydrogen leak detection method is configured to detect all hydrogen leaks occurring in the fuel cell system downstream of the Venturi-type ejector.

It should be noted that the recirculation of hydrogen in the recirculation circuit 60 does not affect the method of detecting hydrogen leaks. This recirculation increases the flow of hydrogen into the fuel cell 12, but does not change the quantity of hydrogen admitted or the quantity of hydrogen consumed.

In a variant of the invention not shown, the supply valve 38 is replaced by an injector providing a discontinuous supply of hydrogen.

In a variant of the invention not shown, the hydrogen supply system 30 comprises a gas regulator arranged between the hydrogen reservoir 32 and the supply valve 38.

In a variant of the invention not shown, the purge valve 54 is replaced by a calibrated orifice, or by a proportional valve, in order to allow continuous purging of the anode compartment 16 of the fuel cell 12.

In an unrepresented variant of the invention, the hydrogen leakage flow Q_{H2.leak} is filtered using a number of filters other than two, for example three different filters. In this case, the result obtained by each of these filters is compared with an associated detection threshold.

The operating mode and variants considered above can be combined to generate new operating modes of the invention.

1-12. (canceled)

13. A method for detecting a hydrogen leak in a fuel cell system, wherein the fuel cell system comprises:
a stack of electrochemical cells forming a fuel cell comprising an anode compartment and a cathode compartment separated by a polymer proton exchange membrane;
a hydrogen supply system comprising a hydrogen reservoir and a supply circuit connecting the hydrogen reservoir to an inlet of the anode compartment of the fuel cell, the supply circuit comprising a Venturi-type ejector;
a recirculation circuit for recirculating hydrogen not consumed by the fuel cell between an outlet of the anode compartment of the fuel cell and the Venturi-type ejector of the supply circuit, the recirculation of the unconsumed hydrogen being driven by the Venturi-type ejector; and
a purge system comprising a valve for purging and draining the anode compartment;
the hydrogen leakage detection method comprising the following steps:
a) calculating the total flow of hydrogen consumed by the fuel cell system;
b) calculating the flow rate of hydrogen admitted by the hydrogen supply system into an inlet pipe of the Venturi-type ejector;
c) determining a leak rate by calculating the difference between the flow rate of admitted hydrogen and the total flow of hydrogen consumed; and
d) detecting a possible hydrogen leak in the fuel cell system by comparing the leak rate against at least one threshold value;
such that the method detects all of the hydrogen leaks that occur in the fuel cell system downstream of the Venturi-type ejector.

14. The method for detecting a hydrogen leak according to claim 4, wherein during step a), the calculation of the total flow rate of hydrogen consumed Q_{H2.out} by the fuel cell system is carried out from the following sum:
$${Q}_{H 2. out} = {Q}_{H 2. {out}_{sto}} + {Q}_{H 2. {out}_{xo}} + {Q}_{H 2. {out}_{purg}}$$
for which:
Q_{H2.out}_{ₛₜₒ} is the base rate of hydrogen consumed by the fuel cell by electrochemical reaction;
Q_{H2.out}_{_{purg}} is the rate of hydrogen lost through the purges in the anode compartment of the fuel cell; and
Q_{H2.out}_{ₓₒ} is the hydrogen flow rate through the polymer proton exchange membrane from the anode compartment to the cathode compartment.

15. The method for detecting hydrogen leakage according to claim 14, wherein during step a), the flow rate of hydrogen lost Q_{H2.out}_{_{purg}} in the purges of the anode compartment of the fuel cell is calculated according to the following equation:
$${Q}_{H 2. {out}_{purg}} = \frac{{MW}_{h 2}}{R \times T} \times {V}_{anode} \times {\dot{P}}_{anode . in}$$
for which:
MWₕ₂ is the molar mass of dihydrogen;
R is the ideal gas constant;
T is the temperature within the anode compartment;
V_{anode} is the volume of the anode compartment; and
\dot{P}_{anode.in} is the pressure gradient measured at the inlet to the anode compartment during a purge.

16. The method for detecting a hydrogen leak according to claim 15, wherein the pressure gradient \dot{P}_{anode.in} is obtained by a constant admission purge method consisting of deferring the re-establishment of the pressure lost in the anode compartment of the fuel cell during a purge by deferring the opening of a hydrogen supply valve of the supply system.

17. The method for detecting a hydrogen leak according to claim 5, wherein during step a), the flow rate of hydrogen consumed by permeation Q_{H2.out}_{ₓₒ} through the polymer proton exchange membrane from the anode compartment to the cathode compartment is calculated according to the following equation:
$${Q}_{H 2. {out}_{xo}} = \frac{{MW}_{h 2} \times N}{2 \times F} \times {J}_{Xo} \times {S}_{membrane}$$
for which:
MWₕ₂ is the molar mass of dihydrogen;
N is the number of electrochemical cells in the fuel cell;
F is Faraday's constant;
J_{Xo} is the crossover current density; and
S_{membrane} is the surface area of the membrane of an electrochemical cell.

18. The method for detecting a hydrogen leak according to claim 13, wherein, during step b), the flow rate of hydrogen admitted Q_{H2.in} by the hydrogen supply system into the inlet pipe of the Venturi-type ejector is calculated according to whether the flow regime occurring within the Venturi-type ejector is a subsonic flow regime or a sonic flow regime.

19. The method for detecting hydrogen leakage according to claim 18, wherein:
when the flow regime is subsonic, the flow of hydrogen admitted Q_{H2.in}_{_{sub}} by the hydrogen supply system into the inlet pipe of the Venturi-type ejector is calculated according to the following equation:
$${Q}_{H 2. {in}_{sub}} = δ \times {P}_{1} \times {A}_{C} \times \sqrt{\frac{2 \times {MW}_{h 2} \times γ}{R \times {T}_{1}}} \times \sqrt{\frac{{( \frac{{P}_{2}}{{P}_{1}} )}^{\frac{2}{γ}} - {( \frac{{P}_{2}}{{P}_{1}} )}^{\frac{1 + γ}{γ}}}{γ - 1}}$$
for which:
P₁ is the pressure of the hydrogen admitted into the inlet pipe of the Venturi-type ejector;
T₁ is the temperature of the hydrogen admitted to the inlet of the Venturi-type ejector;
P₂ is the hydrogen pressure at the outlet of the Venturi-type ejector;
δ is the efficiency of the sonic choke of the Venturi-type ejector;
A_{C} is the smallest cross-section of the sonic choke of the ejector;
MWₕ₂ is the molar mass of dihydrogen;
γ is the adiabatic coefficient of hydrogen; and
R is the ideal gas constant; and
when the flow regime is sonic, the flow of hydrogen admitted Q_{H2.in}_{ₛₒₙ} by the hydrogen supply system into the inlet pipe of the Venturi-type ejector is calculated according to the following equation:
$${Q}_{H 2. {in}_{son}} = δ \times {P}_{1} \times {A}_{C} \times \sqrt{\frac{{MW}_{h 2} \times γ}{R \times {T}_{1}}} \times {( \frac{2}{γ + 1} )}^{\frac{γ + 1}{2 \times ( γ - 1 )}}$$
for which:
P₁ is the pressure of the hydrogen admitted into the inlet pipe of the Venturi-type ejector;
T₁ is the temperature of the hydrogen admitted to the inlet tube of the Venturi-type ejector;
δ is the efficiency of the sonic choke of the Venturi-type ejector;
A_{C} is the smallest cross-section of the sonic choke of the ejector;
MWₕ₂ is the molar mass of dihydrogen;
γ is the adiabatic coefficient of hydrogen; and
R is the ideal gas constant.

20. The method for detecting a hydrogen leak according to claim 13, wherein the leak rate determined in step c) is filtered before comparison with the at least one threshold value.

21. The method for detecting a hydrogen leak according to claim 20, wherein the leak rate determined in step c) is filtered using two different filters and wherein the results obtained by these two filters are compared with two different detection thresholds:
a first leak detection threshold compared with the leak rate filtered with a first-order low-pass filter with a time constant equal to a first value; and
a second leak detection threshold compared with the leak rate filtered with a first-order low-pass filter with a time constant equal to a second value;
wherein the first leak detection threshold has a value greater than that of the second leak detection threshold, and wherein the first time constant value is less than the second time constant value.

22. The method for detecting a hydrogen leak according to claim 13, wherein:
the hydrogen leak detection method is carried out cyclically, in real time; and
steps c) and d) of the hydrogen leak detection method are performed by a computer controlling the fuel cell system at each sampling period of the computer.

23. A fuel cell system for implementing the hydrogen leak detection method of claim 13 comprising:
a stack of electrochemical cells forming a fuel cell comprising an anode compartment and a cathode compartment separated by a polymer proton exchange membrane;
a hydrogen supply system comprising a hydrogen reservoir and a supply circuit connecting the hydrogen reservoir to the inlet of the anode compartment of the fuel cell, the supply circuit comprising a Venturi-type ejector;
a recirculation circuit for recirculating hydrogen not consumed by the fuel cell between the outlet of the anode compartment of the fuel cell and the Venturi-type ejector of the supply circuit, the recirculation of the unconsumed hydrogen being driven by the Venturi-type ejector;
a purge system comprising a valve for purging and draining the anode compartment; and
a computer configured for implementing steps a) to d) of the hydrogen leak detection method.

24. The fuel cell system according to claim 23, wherein the fuel cell system further comprises a pressure sensor and a temperature sensor arranged upstream of the Venturi-type ejector and a pressure sensor arranged downstream of the Venturi-type ejector.
